(19) United States
(12) Patent Application Publication
(10) Pub. No.: US 2024/0319260 A1
(43) Pub. Date: Sep. 26, 2024

(54) STATE TRANSITION CONTROL FOR PARAMETRIC MEASUREMENT UNIT

(71) Applicant: Texas Instruments Incorporated, Dallas, TX (US)

(72) Inventors: Tanmay Neema, Bangalore (IN); Rajavelu Thinakaran, BANGALORE (IN); Gautam Salil Nandi, Bangalore (IN); Vishal Monteiro, BANGALORE (IN); Deepak Kumar Meher, Bangalore (IN)

(21) Appl. No.: 18/478,825

(22) Filed: Sep. 29, 2023

(30) Foreign Application Priority Data
Mar. 23, 2023 (IN) 202341020378

(51) Int. Cl. G01R 31/28

(52) U.S. Cl. CPC G01R 31/2834; G01R 31/2889

(57) ABSTRACT

In described examples, a test control circuit includes a subsystem and a transition control circuit. The subsystem outputs test signals to, and receives and measures response signals of, a device under test (DUT). The transition control circuit operates the test control circuit in response to a first operational state information indicating a first mode and a first set of configuration settings; receives a Transition Trigger signal and a second operational state information indicating a second mode and a second set of configuration settings; and, by performing allowed mode changes and in response to receiving the Transition Trigger signal, transitions the test control circuit to operating in response to the second operational state information. Allowed mode changes are restricted to: from a DUT driving mode to a DUT non-driving mode, from a DUT non-driving mode to another DUT non-driving mode, or from a DUT non-driving mode to a DUT driving mode.

### CROSS-REFERENCE TO RELATED APPLICATION

This application claims the benefit of, and priority to, India Provisional Application No. 202341020378, filed Mar. 23, 2023, which is incorporated herein by reference.

### TECHNICAL FIELD

This application relates generally to automatic test equipment (ATE), and more particularly to controlling an operational state of a parametric measurement unit.

### BACKGROUND

An ATE is used to perform automatically sequenced tests on one or more devices under test (DUTs), such as integrated circuits (ICs) or system-on-chips (SoCs). In some examples, an ATE is used to perform wafer testing, or to test packaged parts. In some examples, an ATE is used to test avionics, or to test electronic modules for automobiles or industrial systems. Safety or other criteria may require ATE testing prior to part deployment. Accordingly, where an ATE testing is required prior to part installation, a rate at which the ATE testing can be completed for a part limits a manufacturing throughput for the part. In some examples, sequences of test signals to be applied, and corresponding DUT internal and output signals to be measured, are programmed into an ATE in response to DUT design.

### SUMMARY

In described examples, a test control circuit includes a subsystem and a transition control circuit. The subsystem outputs test signals to, and receives and measures response signals of, a device under test (DUT). The transition control circuit operates the test control circuit in response to a first operational state information indicating a first mode and a first set of configuration settings; receives a Transition Trigger signal and a second operational state information indicating a second mode and a second set of configuration settings; and, by performing allowed mode changes and in response to receiving the Transition Trigger signal, transitions the test control circuit to operating in response to the second operational state information. Allowed mode changes are restricted to: from a DUT driving mode to a DUT non-driving mode, from a DUT non-driving mode to another DUT non-driving mode, or from a DUT non-driving mode to a DUT driving mode.

### BRIEF DESCRIPTION OF THE DRAWINGS

FIG. 1 is a functional block diagram of an example ATE system.

FIG. 2 is a functional block diagram of an example state register block.

FIG. 3 is an example process for transitioning between operating states of the parametric measurement unit of FIG. 1.

FIG. 4 is an example functional block diagram of the control circuit of FIG. 1.

FIG. 5 is a state map for an example state machine for transitioning between operating modes of the parametric measurement unit of FIG. 1.

FIG. 6A is a first example operating state transition super-set sequence for the parametric measurement unit of FIG. 1.

FIG. 6B is a second example operating state transition super-set sequence for the parametric measurement unit of FIG. 1.

FIG. 6C is a third example operating state transition super-set sequence for the parametric measurement unit of FIG. 1.

FIG. 7 is another example process for transitioning between operating states of the parametric measurement unit of FIG. 1.

### DETAILED DESCRIPTION

In some examples, an ATE uses parametric measurement units (PMUs) to provide test signals for, and measure internal or output signal levels of, respective DUTs. A set of test signals provided by a PMU, with corresponding sense settings, corresponds to an operational state of the PMU. An operational state of the PMU corresponds to a mode of the PMU, such as force voltage mode, force current mode, high impedance voltage mode, or high impedance current mode; and a set of configuration settings, such as force voltage range, offset digital-to-analog (DAC) code, or force DAC code. Testing of a DUT can include sequencing multiple different operational states.

Transitioning a PMU directly from a DUT driving mode to a different DUT driving mode can result in signal level glitches, such as voltage or current spikes. Herein, DUT driving mode refers to a mode in which the PMU drives a signal (such as a test signal) to the DUT. Changing configuration settings without changing the mode of the PMU can also cause glitches. In some examples, such glitches can cause functional instability in a corresponding DUT, which may lead to invalid test results, or can damage the DUT.

In some examples, glitches related to PMU state transitions can be avoided using what is referred to herein as a minimum unit transition path. To transition from a starting mode to a finishing mode, and from a starting set of configuration settings to a finishing set of configuration settings, the mode of the PMU is changed to a nearest DUT non-driving mode, such as a high impedance voltage mode or a high impedance current mode. From the DUT non-driving mode, the mode of the PMU is then changed to another DUT non-driving mode or to a final mode, which can be a DUT driving mode or a DUT non-driving mode. Configuration settings are changed at modes, and in an order, to reliably avoid glitching. Configuration changes are performed or skipped in response to pre-specified conditions.

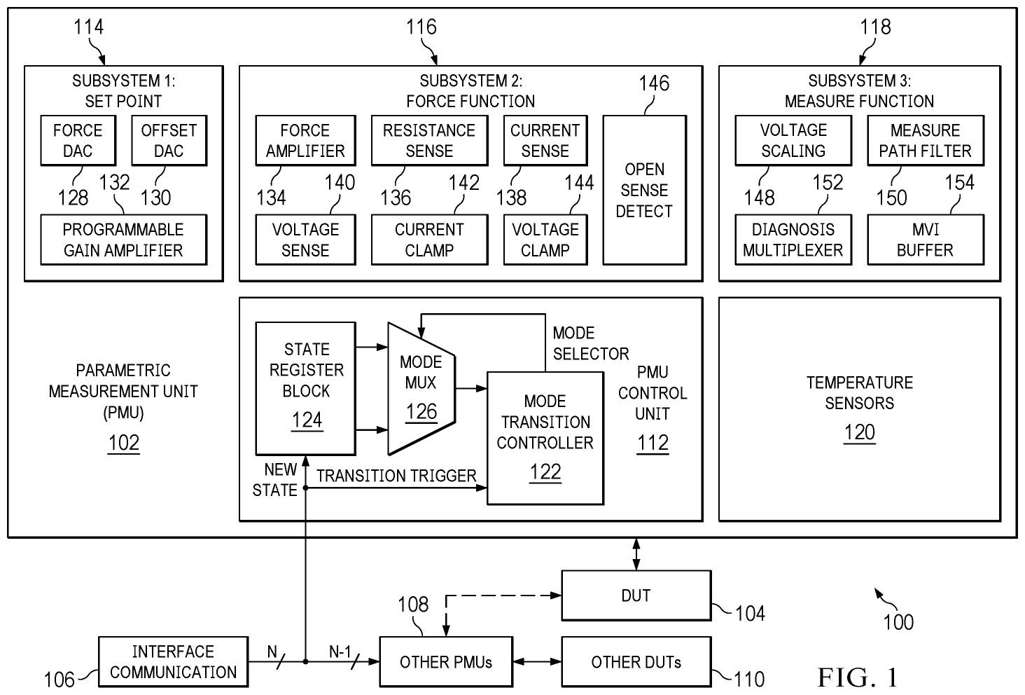

FIG. 1 is a functional block diagram of an example ATE system 100. The ATE system includes a parametric measurement unit (PMU) 102, a DUT 104 controlled by the PMU 102, an interface communication circuit 106, other PMUs 108, and other DUTs 110. DUTs each have a (variable) first number of inputs (such as pins) that can receive test signals, and PMUs each have a (variable) second number of outputs that can provide test signals. The first number and the second number may be different. Accordingly, the DUT 104 may be controlled by one or more of the other PMUs 108 in addition to the PMU 102 (indicated by a dotted line). Similarly, the other DUTs 110 are respectively controlled by one or more of the other PMUs 108. Here, a PMU controlling a DUT refers to the PMU providing test signals to, and receiving response signals from, the DUT. The interface communication circuit 106 distributes sequenced operational state setting information to the PMU 102 and the other PMUs 108 to cause the various PMUs 102 and 108 to apply selected test signals to, and receive response signals from, respective ones of the various DUTs 104 and 110.

The PMU 102 includes a PMU control circuit 112, a set point subsystem (subsystem 1) 114, a force function subsystem (subsystem 2) 116, a measure function subsystem (subsystem 3) 118, and temperature sensors 120. The PMU control circuit 112 includes a mode transition controller 122, a state register block 124, and a mode multiplexer (MUX) 126.

The set point subsystem 114 includes a force DAC 128, an offset DAC 130, and a programmable gain amplifier 132. The force function subsystem 116 includes a force amplifier 134, a resistance sense circuit 136, a current sense circuit 138, a voltage sense circuit 140, a current clamp 142, a voltage clamp 144, and an open sense detect (OSD) circuit 146. The measure function subsystem 118 includes a voltage scaling circuit 148, a measure path filter 150, a diagnosis MUX 152, and a measure voltage/current (MVI) buffer 154.

In some examples, the PMU 102 includes additional, fewer, and/or different subsystems. In some examples, the set point, force function, and measure function subsystems 114, 116, and 118 respectively include additional, fewer, and/or different functional blocks.

The interface communication circuit 106 is connected to provide new PMU 102 operating state information to the state register block 124 and a Transition Trigger to the respective mode transition controllers 122 of a number N different PMUs. The N different PMUs include the PMU 102 and N minus one other PMUs 108. A change in a value of the Transition Trigger signals the PMU control circuit 112 to transition the PMU 102 (or other PMU 108) to a new operating state stored by the state register block 124.

In some examples, the interface communication circuit 106 is connected to control the N PMUs (that is, the PMU 102 and other PMUs 108) using N communication buses, such as serial buses. Each communication bus may be multiple lines wide. In some examples, N equals 64. In some examples, the interface communication circuit 106 serially provides the new state and the Transition Trigger to respective ones of the PMU 102 and other PMUs 108 via a corresponding bus. In some examples, a communication bus may include a separate connection from the interface communication circuit 106 to a dedicated input (such as a pin) of the PMU 102 (or other PMU 108) to provide a Transition Trigger signal.

The PMU 102 is connected to provide test signals to, and to receive and sense internal and/or output signals (response signals) generated by, the DUT 104. The N minus one other PMUs 108 are connected to provide test signals to, and to receive and sense internal and/or output signals generated by, respective ones of the DUT 104 or other DUTs 110. As described above, a DUT 104 or other DUT 110 may respectively receive test signals from, and provide response signals to, one or more of the PMU 102 and other PMUs 108.

The PMU 102 and other PMUs 108 provide test signals to the DUT 104 or other DUTs 110, and receive and sense signals of the DUT 104 or other DUTs 110 (respectively), according to operating state information stored by the respective state register blocks 124 of the PMU 102 or other PMUs 108. In some examples, connections of the PMU 102 to and from the DUT 104, and of the other PMUs 108 to and from the DUT 104 and/or other DUTs 110, are multiple lines corresponding to various different test signals and response signals.

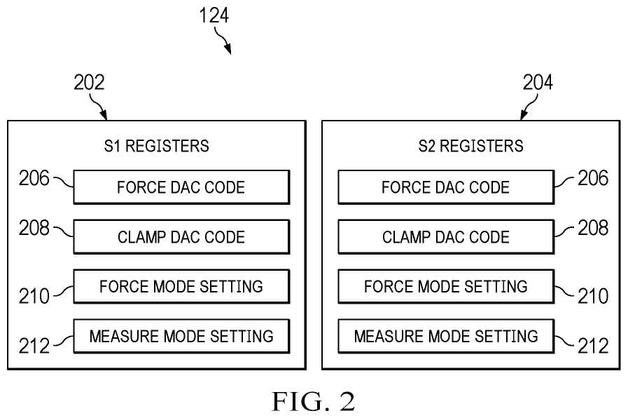

The state register block 124 provides state information (mode and configuration information) from each of two different sets of registers (see FIG. 2) to the mode MUX 126. The mode MUX 126 also receives a Mode Selector signal from the mode transition controller 122. The mode MUX 126 provides state information from one of the two different sets of registers of the state register block 124 to the mode transition controller 122. The mode MUX 126 selects between the two different sets of state information in response to a value of the Mode Selector signal. The mode transition controller 122 changes the value of the Mode Selector signal in response to the Transition Trigger. Accordingly, after the Transition Trigger changes value, the value of the Mode Selector signal is changed, the mode MUX 126 provides a new, different set of state information to the mode transition controller 122, and the mode transition controller 122 loads the new set of state information. Once signal values corresponding to the new set of state information settle, the PMU 102 operates (providing test signals to, and sensing resulting response signals of, the DUT 104) using the new set of state information. Herein, settle refers to corresponding signals reaching a stable state, or a sufficiently stable state within test design parameters for the signals to be applied for test of the DUT 104.

FIG. 2 is a functional block diagram of an example state register block 124. The same reference numbers or other reference designators are used in the drawings to designate the same or similar (structurally and/or functionally) features. The state register block 124 includes a first set of state registers (S1 registers) 202 and a second set of state registers (S2 registers) 204. The S1 registers 202 and S2 registers 204 each respectively include registers storing a force DAC code 206, a clamp DAC code 208, a force mode setting 210, and a measure mode setting 212. In some examples, the force mode setting 210 corresponds to a mode of the PMU 102, and the force DAC code 206, a clamp DAC code 208, and the measure mode setting 212 correspond to configuration settings of the PMU 102.

In some examples, the Transition Trigger signal can have one of two values, corresponding to the number of distinct sets of state information stored by the state register block 124. A first value, such as a zero, causes the PMU 102 to enter and/or maintain an operational state corresponding to the state information stored in the S1 registers 202. A second value, such as a one, causes the PMU 102 to enter and/or maintain an operational state corresponding to the state information stored in the S2 registers 204.

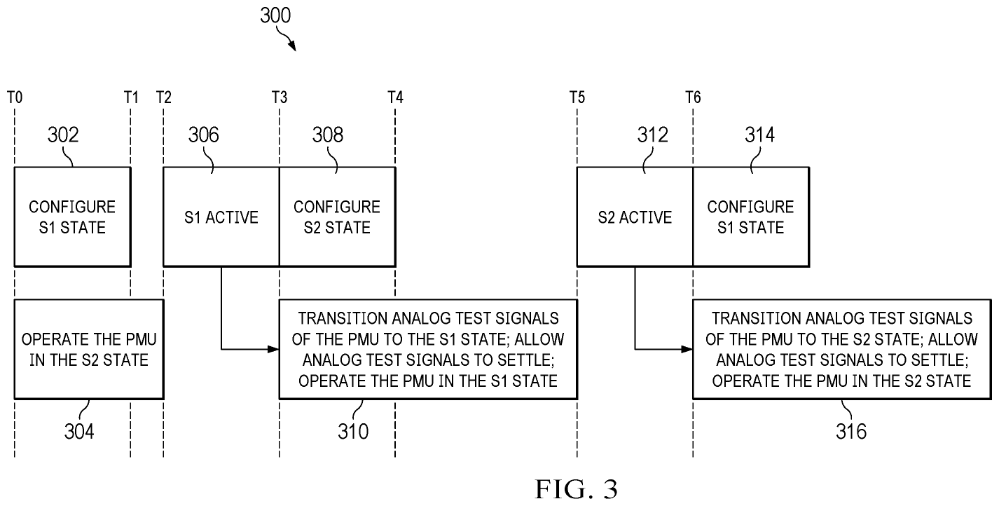

FIG. 3 is an example process 300 for transitioning between operating states of the PMU 102 of FIG. 1. From time T0 to time T1, in step 302, the interface communication circuit 106 serially loads the S1 registers 202 with state settings corresponding to a new PMU operating state, including mode and configuration settings. Meanwhile, from time T0 time T2, in step 304, the PMU 102 operates in a state corresponding to the state information stored in the S2 registers 204.

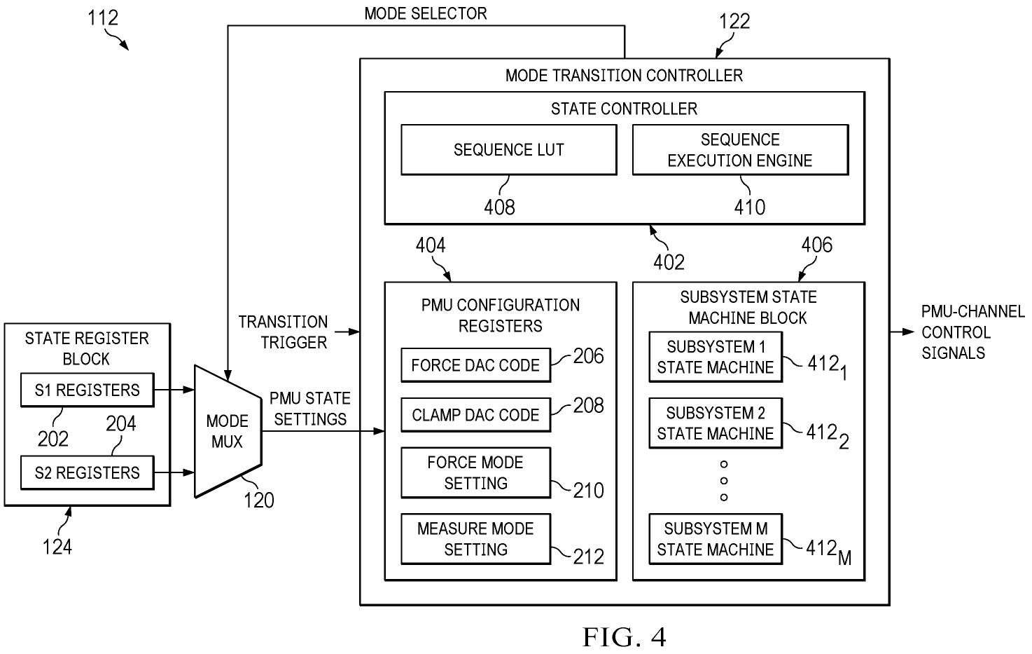

At time T2, in step 306, operation of the PMU 102 using the operating state stored by the S1 registers 202 (see step 302) is activated. Responsively, the PMU 102 stops operating using the state stored by the S2 registers 204. The described activation corresponds to the mode transition controller 122 receiving the Transition Trigger with the new (changed) value corresponding to the state information stored in the S1 registers 202, and changing the value of the Mode Selector signal to correspond to the mode MUX 126 input corresponding to the output of the S1 registers 202; and loading the contents of the S1 registers 202 into PMU configuration registers 404 of the mode transition controller 402 (see FIG. 4). As described above, the Transition Trigger can be received via a dedicated pin or other input line. Accordingly, step 306 (and similarly, step 312) can be triggered using a dedicated pin or other input line.

From time T3 to time T4, in step 308, while step 310 (sequenced loading of and execution according to new state information) is ongoing, the interface communication circuit 106 loads new state settings into the S2 registers 204. Accordingly, sets of new state settings are alternatingly loaded into the S1 registers 202 and the S2 registers 204, so that the interface communication circuit 106 loads new state settings into either the S1 or S2 registers 202 or 204 while the state settings in the other one of the S1 or S2 registers 202 or 204 are being used to operate the PMU 102.

From time T3 to time T5, in step 310, the mode transition controller 122 transitions the PMU 102 from providing analog test signals and measuring DUT 104 response signals using the state settings stored by the S1 registers 202 to providing analog test signals and measuring DUT 104 response signals using the state settings stored by the S1 registers 202. Step 310 can be described as performed in three parts. First, updating digital settings, corresponding to, in a sequential manner, loading the contents of the S1 registers 202 into PMU configuration registers 404 of the mode transition controller 402 (see FIG. 4). Second, commands corresponding to updated digital settings are executed, and corresponding analog signals to be provided by the PMU 102 to the DUT 104 are allowed to settle. That is, while new state information is loaded into PMU configuration registers 404, the mode transition controller 402 contemporaneously executes commands responsive to the new register contents. In some examples, following execution of a command (e.g., each command) that causes an analog signal to change, the analog signal is allowed to settle prior to execution of the next command. Third, the PMU 102 measures response signals of the DUT 104 corresponding to the analog signals provided by the PMU 102.

In some examples, providing a set of new state information to, and storing the new state information on, the PMU 102 prior to changing the value of the Transition Trigger signal enables the mode transition controller 402 to retrieve the new state information and execute corresponding commands in a pre-determined sequence stored on the PMU 102. In some examples, this enables separation of test signal sequence design from design of glitchless (or glitch-reduced) transitions from test signal to test signal. This enables simplification of DUT test design, reduction in DUT test design cost, improved reliability of DUT test, and improved manufactured part quality.

From time T5 to time T6, in step 312, operation of the PMU 102 using the operating state stored by the S2 registers 204 (see step 308) is activated. Responsively, the PMU 102 stops operating using the state stored by the S1 registers 202. This corresponds to the mode transition controller 122 receiving the Transition Trigger with the new (changed) value corresponding to the state information stored in the S2 registers 204, and changing the value of the Mode Selector signal to correspond to the mode MUX 126 input corresponding to the output of the S2 registers 204.

Starting at time T6, in step 314, while step 316 (sequenced loading of and execution according to new state information) is ongoing, the interface communication circuit 106 loads new state settings into the S1 registers 202. Also starting at time T6, in step 316, the mode transition controller 122 transitions the PMU 102 from providing analog test signals and measuring DUT 104 response signals using the state settings stored by the S1 registers 202 to providing analog test signals and measuring DUT 104 response signals using the state settings stored by the S2 registers 204. This corresponds to, as in step 310, updating digital settings, executing commands to update analog signals provided by the PMU 102 and allowing the analog signals to settle, and measuring DUT 104 response signals.

FIG. 4 is an example functional block diagram of the PMU control circuit 112 of FIG. 1. The mode transition controller 122 includes a state controller 402, PMU configuration registers 404, and a subsystem state machine block 406. The state controller 402 includes a sequence lookup table (LUT) 408 and a sequence execution circuit 410 (also referred to as a sequence execution engine 410).

The subsystem state machine block 406 includes a number M subsystem state machines, corresponding to a first subsystem state machine (subsystem 1 state machine) 412₁ through an M^{th} subsystem state machine 412_{M}. The number M is the number of subsystems in the PMU 102. In the illustrated example, M=3, with the set point subsystem 114, the force function subsystem 116, and the measure function subsystem 118. Subsystem state machines 412 are numbered 412 in aggregate, and are individually numbered [412-sub-number], where the subscript corresponds to an index number of the subsystem. In some examples, PMU functional blocks are grouped together into subsystems based on ease of implementation. In some examples, other considerations are used to determine subsystem grouping.

The sequence LUT 408 stores a set of state transition super-set sequences. These sequences define an order of mode transitions, configuration changes, wait times, and other commands to enable the PMU 102 to change operating state with reduced or eliminated glitching. The sequence LUT 408 stores super-set sequences describing each possible operating state transition, where each super-set sequence corresponds to a unique pair of a starting mode and a final mode. For example, in a PMU 102 with seven different modes available, the sequence LUT 408 will store forty-nine different super-set sequences, that is, the square of the number of available modes. This enables provision of pre-determined state transition control sequences that reduce or eliminate glitched signals of the PMU 102 corresponding to PMU 102 state transitions.

Super-set sequences are so-called because they refer to sequences that include all mode changes needed to traverse from a starting mode to a corresponding final mode that together can be viewed as identifying the super-set sequence; and include all configuration changes that may be performed during that traversal. Some configuration changes specified by a super-set sequence may be skipped, depending on new configuration setting details. In some examples, a skip condition 610 may also be defined for a state transition command 608 corresponding to a mode transition. Accordingly, a super-set sequence specifies a super-set of (a set equal to or greater than a set of) actual mode and configuration changes to be performed for a particular operating state transition for a corresponding starting mode and final mode.

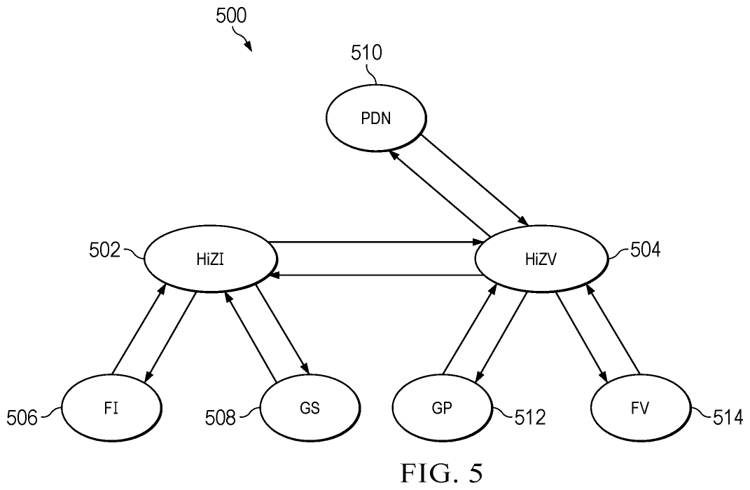

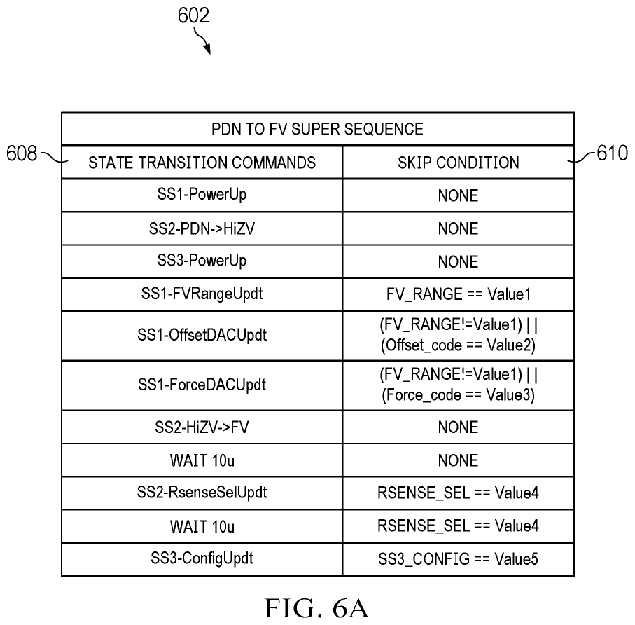

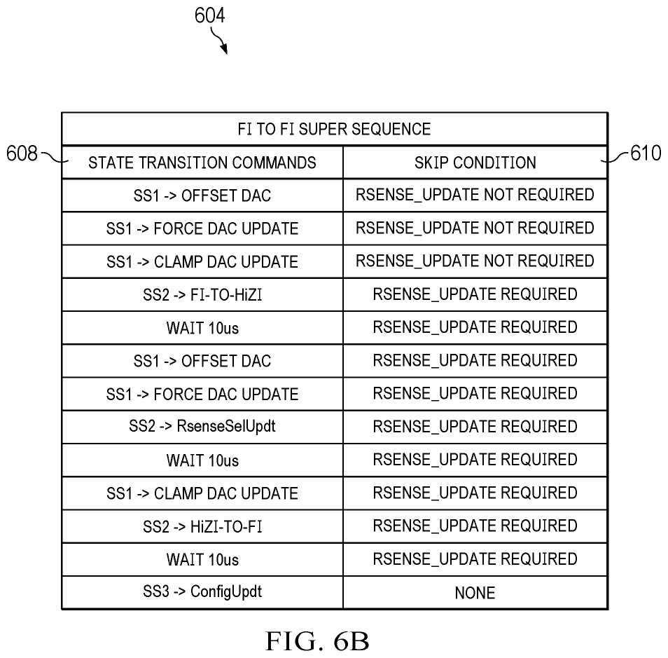

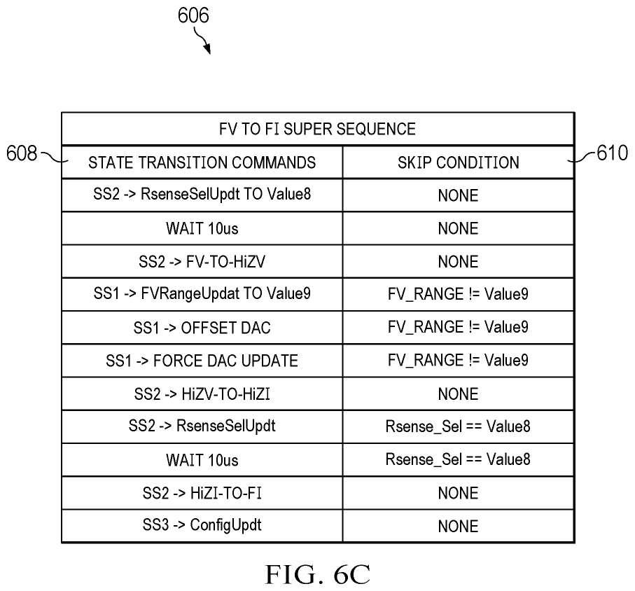

Use of state transition super-set sequences is enabled by minimum unit transition paths. State transition super-set sequences and minimum unit transition paths are further described with respect to FIGS. 5 and 6.

In response to current state settings of the PMU 102 as stored by the PMU configuration registers 404, and new state settings of the PMU 102 as provided by the state register block 124 via the mode MUX 120, the sequence LUT 408 provides a state transition super-set sequence to the sequence execution engine 410. The mode MUX 120 provides PMU state settings to the PMU configuration registers 404, as described with respect to FIG. 3. The state settings provided by the mode MUX 120 determine the state transition super-set sequence called within the sequence LUT 408, and the resulting mode transition path and configuration change order provided by the sequence LUT 408 to the sequence execution engine 410.

The sequence execution engine 410 translates the state transition super-set sequence provided by the sequence LUT 408 into a set of control sequences. The sequence execution engine 410 provides these control sequences to the subsystem state machines 412 of the subsystem state machine block 406. Responsive to the control sequences provided by the sequence execution engine 410, the subsystem state machines 412 provide control signals to respective subsystems of the PMU 102 (the set point, force function, and measure function subsystems 114, 116, and 118). Responsive to the control signals, the subsystems transition to the new state specified by the new PMU state settings. After analog signals generated by the subsystems of the PMU 102 settle, the PMU 102 provides test signals to, and senses response signals of, the DUT 104 according to the new PMU state settings. Control signals provided by the subsystem state machines 412 to the subsystems of the PMU 102 are also referred to as PMU-channel control signals.

FIG. 5 is a state map 500 for an example state machine for transitioning between operating modes of the PMU 102 of FIG. 1. In some examples, the state map 500 corresponds to different sets of switches closing and opening to connect and disconnect functional blocks used by corresponding operational modes of the PMU 102. The state map 500 includes a high impedance current mode (HiZI) 502, a high impedance voltage mode (HiZV) 504, a force current mode (FI) 506, a gang secondary mode (GS) 508, a power down mode (PDN) 510, a gang primary mode (GP) 512, and a force voltage mode (FV) 514. HiZI 502 and HiZV 504 are configured as DUT non-driver modes. The other modes are configured as DUT driver modes.

A DUT non-driver mode can transition directly to another DUT non-driver mode, or to one or more DUT driver modes. In some examples, DUT driver modes can transition directly only to a DUT non-driver mode. A DUT driver mode is a mode in which the PMU 102 drives a signal to an input (such as a pin) of the DUT 104. A DUT non-driver mode is a mode in which the PMU 102 does not drive a signal to an input of the DUT 104. Because the PMU 102 does not drive a signal to an input of the DUT 104 in a DUT non-driver mode, the likelihood of the PMU 102 providing a glitched signal to the DUT 104 while the PMU 102 is in a DUT non-driver mode is reduced or eliminated. In some examples, a DUT non-driver mode is designed to be additionally stringent in signal control: a DUT non-driver mode can be designed so that the PMU 102 is actively prevented from providing a signal to an input of the DUT 104 while in the DUT non-driver mode.

In some examples, the HiZI mode 502 and the HiZV mode 504 are examples of stringent DUT non-driver modes. The HiZI mode 502 is a force current mode in which the PMU 102 actively forces a zero ampere signal (a null signal) on a corresponding output connected to an input of the DUT 104. In the HiZV mode 504, output of the PMU 102 is disconnected from the DUT 104 by an open switch, such as one or more turned-off transistors of the PMU 102. In some examples, an open switch leaks current. Accordingly, negative feedback is used to drive the leakage signal to zero voltage (a null signal). In some examples, a DUT non-driver mode to which a DUT driver mode can transition is selected in response to similarity of switch topology of the respective modes.

Accordingly, rather than 42 different possible direct mode transitions (each mode to each other mode), there are only 12 possible direct mode transitions—each added mode after the first contributes two additional paths: one to the added mode, and one from the added mode. This means that for P available modes, there are 2×(P−1) available direct mode transitions.

This reduced set of direct mode transitions are referred to as minimum unit transitions. In the illustrated example, HiZI 502 and HiZV 504 can transition to and from each other. FI 506 and GS 508 can transition to and from HiZI 502. PDN 510, GM 512, and FV 514 can each transition to and from HiZV 504. As described, minimum unit transitions reduce the number of possible mode change paths that need to be described by super-set sequences. Minimum unit transitions also limit mode change paths to paths that enable design of super-set sequences to reliably avoid glitching. In some examples, super-set sequence design includes selection of modes along a transition path in which to safely (glitchlessly, or without glitches that can impact test sequence and measurement performance) perform configuration setting changes, and selection of wait instructions and times to enable signals to settle before proceeding to a next super-set sequence instruction.

Minimum unit transitions are assembled to provide minimum unit transition paths. In some examples, a minimum unit transition path can be used to transition from FI 506 to PDN 510: FI 506 to HiZI 502, to HiZV 504, to PDN 510. Similarly, a minimum unit transition path can be used to transition from GP 512 to FV 514: GP 512 to HiZV 504 to FV 514. Other examples will be understood from FIG. 5.

FIG. 6A is a first example operating state transition super-set sequence 602 for the PMU 102 of FIG. 1. FIG. 6B is a second example operating state transition super-set sequence 604 for the PMU 102 of FIG. 1. FIG. 6C is a third example operating state transition super-set sequence 604 for the PMU 102 of FIG. 1. Each of the super-set sequences 602, 604, and 606 includes a list of state transition commands 608 and a list of corresponding skip conditions 610.

Different ones of the super-set sequences 602, 604, and 606 correspond to a different combination of initial mode and final mode. In the examples shown the first super-set sequence 602 corresponds to a transition from PDN 510 to FV 514, the second super-set sequence 604 corresponds to a transition from FI 506 to FI 506, and the third super-set sequence 606 corresponds to a transition from FV 514 to FI 506. The first super-set sequence 602 describes a minimum unit transition path from PDN 510, to HiZV 504, to FV 514. The second super-set sequence 604 describes a minimum unit transition path from FI 506, to HiZI 502, to FI 506. The third super-set sequence 606 describes a minimum unit transition path from FV 514, HiZV 504, to HiZI 502, to FI 506.

A state transition command 608 includes an indication of a subsystem of the PMU 102 (subsystem 1 (SS1), subsystem 2 (SS2), or subsystem 3 (SS3)) to receive control signals corresponding to the state transition command 608. This indication also points to the subsystem state machine 412 that generates the respective state transition command 608.

Each super-set sequence, such as the first, second, and third super-set sequences 602, 604, and 606, includes state transition commands 608 corresponding to all configuration changes that can be made in transitioning along a corresponding minimum unit transition path. State transition commands 608 corresponding to configuration changes are sequenced, within respective super-set sequences, to avoid (or reduce) glitching.

Some configuration settings are not changed under some conditions. That is, while super-set sequences include state transition commands 608 corresponding to all possible configuration changes for that path, not all state transitions include all possible configuration changes. Accordingly, some state transition commands 608 have a corresponding skip condition 610 that causes the state transition command 608 to be skipped at execution time if the skip condition 610 is satisfied. In the illustrated examples, state transition commands 608 that are not conditionally skipped list their skip condition 610 as “none.” In some examples, certain other state transition commands 608 in a super-set sequence can also be skipped, so that the super-set sequence includes corresponding skip conditions 610 for those skippable state transition commands 608.

In some examples, skip conditions 610 specify skipping a corresponding state transition command 608 that causes a mode transition or changes a configuration setting. In some examples, a mode transition can have a corresponding skip condition 610 if the super-set sequence (such as the second super-set sequence 604) corresponds to transitioning from an initial DUT driving mode, to a DUT non-driving mode to enable configuration setting changes (such as potentially glitch-inducing configuration setting changes), and back to the initial DUT driving mode. If the state transition command(s) 608 corresponding to configuration setting changes that require the transition to a DUT non-driving mode is skipped, then the state transition commands 608 corresponding to the mode transitions may also be skipped. That is, the skip conditions 610 for these state transition commands 608 may be the same or partially the same. In some examples, a state transition command 608 corresponding to configuration setting changes is skipped in response to new PMU settings that specify no change of the configuration setting, or that specify changing the configuration setting to an invalid value.

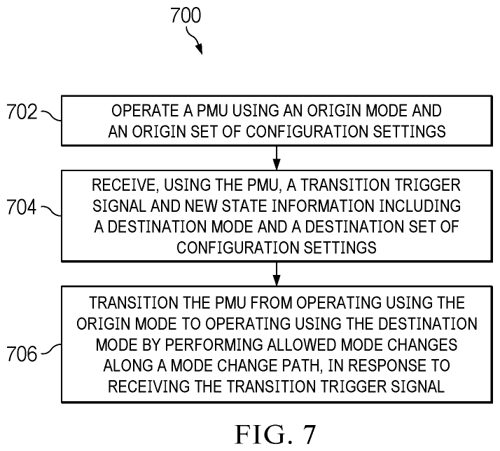

FIG. 7 is another example process 700 for transitioning between operating states of the parametric measurement unit of FIG. 1. In step 702, a PMU is operated using an origin mode and an origin set of configuration settings. In step 704, the PMU receives a Transition Trigger signal and new state information including a destination mode and a destination set of configuration settings. In step 706, the PMU transitions from operating using the origin mode to operating using the destination mode by performing allowed mode changes along a mode change path, in response to receiving the Transition Trigger signal. In some examples, allowed mode changes are restricted to: from a DUT driver mode to a DUT non-driver mode, from a DUT non-driver mode to another DUT non-driver mode, or from a DUT non-driver mode to a DUT driver mode.

Modifications are possible in the described examples, and other examples are possible within the scope of the claims.

In some examples, a PMU provides test signals to, and receives response signals from, multiple DUTs.

In some examples, a transition trigger signal can have an ENABLE value that causes a transition from an operational state corresponding to a first set of state information, to an operational state corresponding to a second set of state information.

In some examples, a sequence LUT will store a number of state transition super-set sequences that is different from (greater or less than) the square of the number of available modes of the PMU.

In some examples, skip conditions other than those described are used. In some examples, state transition commands corresponding to mode transitions may be skipped under other conditions than those described. In some examples, state transition commands corresponding to configuration setting changes may be skipped under other conditions than those described.

In some examples, a memory other than an LUT is used to store state transition super-set sequences.

In some examples, a mode transition from a DUT driver mode directly to a different DUT driver mode is allowed. In some examples, an LUT includes a state transition super-set sequence corresponding to a mode transition from a DUT driver mode directly to a different DUT driver mode.

In some examples, such as where mode transitions from a DUT driver mode to a DUT driver mode are allowed, there are more than 2(P−1) available direct mode transitions.

In some examples, methods and systems described above can be applied to a PMU, a sense measurement unit (SMU), a device power supply (DPS), or another test control circuit.

In some examples, a PMU, SMU, or DPS only drives a single test signal channel. In some examples, a PMU, SMU, or DPS drives multiple output channels, only one of which is a test signal channel. In some examples, the PMU drives signals provided to the DUT in a channel other than a test signal channel while the PMU is in a DUT non-driving mode.

In some examples, the ATE system 100 of FIG. 1 is implemented using analog or digital circuits, or a combination thereof. In some examples, the ATE system 100 is implemented using a processor such as a DSP and/or a microprocessor.

In some examples, the state register block 124 of FIG. 2 is implemented using analog or digital circuits, or a combination thereof. In some examples, the state register block 124 is implemented using a processor such as a DSP and/or a microprocessor.

In some examples, the PMU control circuit 112 of FIG. 4 is implemented using analog or digital circuits, or a combination thereof. In some examples, the PMU control circuit 112 is implemented using a processor such as a DSP and/or a microprocessor.

In some examples, the process 300 of FIG. 3 is implemented using programmable circuits executing software or firmware.

In some examples, the state map 500 of FIG. 5 is implemented using different switch configurations changing connections between various functional blocks of an IC such as a PMU, SMU, or DPS, and/or using programmable circuits executing software or firmware.

In some examples, the process 700 of FIG. 7 is implemented using programmable circuits executing software or firmware.

In some examples, memory structures used to implement the state register block 124 of FIG. 2 include static random access memory (SRAM), dynamic random access memory (DRAM), or Flash memory.

In some examples, memory structures used to implement the sequence LUT 400 of FIG. 4 include static random access memory (SRAM), dynamic random access memory (DRAM), or Flash memory.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin”, “ball” and “lead” are used interchangeably. Unless specifically stated to the contrary, these terms are generally used to mean an interconnection between or a terminus of a device element, a circuit element, an integrated circuit, a device or other electronics or semiconductor component.

While certain elements of the described examples may be included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

What is claimed is:

1. A method comprising:
operating a test control circuit in response to a first mode and a first set of configuration settings;
receiving, in the test control circuit, a transition trigger signal and state information indicating a second mode and a second set of configuration settings; and
transitioning the test control circuit, in response to receiving the transition trigger signal, from operating in response to the first mode to operating in response to the second mode by performing allowed mode changes;
wherein allowed mode changes are restricted to: from a DUT driving mode to a DUT non-driving mode, from a DUT non-driving mode to another DUT non-driving mode, or from a DUT non-driving mode to a DUT driving mode.

2. The method of claim 1, wherein the test control circuit does not drive a test signal to the DUT while the test control circuit is in a DUT non-driving mode.

3. The method of claim 1, wherein the test control circuit transitions from operating in response to the first mode to operating in response to the second mode along a shortest mode change path according to the allowed mode changes.

4. The method of claim 1, wherein, in a DUT non-driving mode, the test control circuit prevents active or leakage signal transmission from the test control circuit to the DUT, or the test control circuit forces a zero current signal on a line coupling the test control circuit to the DUT.

5. The method of claim 1, wherein the transitioning includes looking up an operating state transition super-set sequence in a lookup table of the test control circuit, and sequencing commands in response to the super-set sequence to transition from operating in response to the first mode and the first set of configuration settings to operating in response to the second mode and the second configuration settings.

6. The method of claim 5,
wherein the operating state transition super-set sequence includes commands to cause a state control circuit to generate signals to cause the test control circuit to change modes as specified by a mode change path accordingly to the allowed mode changes; and
wherein the operating state transition super-set sequence includes commands corresponding to the state control circuit generating signals to cause the test control circuit to change each configuration setting.

7. The method of claim 6, wherein the operating state transition super-set sequence includes a skip condition to cause the state control circuit to skip a configuration setting change command in the operating state transition super-set sequence in response to a designated signal value.

8. A test control circuit comprising:
a subsystem configured to output test signals to a device under test (DUT), and to receive and perform measurement of response signals of the DUT; and
a transition control circuit configured to:
operate the test control circuit in response to a first operational state information, the first operational state information indicating a first mode and a first set of configuration settings;
receive a transition trigger signal and a second operational state information, the second operational state information indicating a second mode and a second set of configuration settings; and
transition the test control circuit, in response to receiving the transition trigger signal, to operating in response to the second operational state information by performing allowed mode changes;
wherein allowed mode changes are restricted to: from a DUT driving mode to a DUT non-driving mode, from a DUT non-driving mode to another DUT non-driving mode, or from a DUT non-driving mode to a DUT driving mode.

9. The test control circuit of claim 8, wherein the test control circuit is configured to not drive a signal to the DUT while the test control circuit is in the DUT non-driving mode.

10. The test control circuit of claim 8, wherein the transition control circuit includes:
a control output;
a state register block including a first output and a second output, the state register block configured to store the first state and the second state;
a selection circuit including a first data input, a second data input, a control input, and an output, the first data input of the selection circuit coupled to the first output of the state register block, the second data input of the selection circuit coupled to the second output of the state register block, and the control input of the selection circuit is coupled to the control output of the control circuit, so that the selection circuit outputs the first data input of the selection circuit or the second data input of the selection circuit in response to the control output of the control circuit.

11. The test control circuit of claim 8, wherein the test control circuit includes a driving prevention circuit, the driving prevention circuit configured to:
drive a zero current signal to the DUT; or
use negative feedback to reduce a leakage signal from an open switch of the test control circuit adapted to couple an output of the test control circuit to an input of the DUT.

12. The test control circuit of claim 8, wherein the control circuit includes a lookup table configured to store multiple operating state transition super-set sequences, different operating state transition super-set sequences corresponding to different possible mode change paths according to the allowed mode changes.

13. The test control circuit of claim 12, wherein the transition control circuit includes an execution circuit configured to translate an operating state transition super-set sequence into a sequence of control signals for controlling the subsystem.

14. An automatic test equipment (ATE) comprising:
multiple test control circuits, ones of the test control circuits comprising:
a subsystem configured to output test signals to one of multiple devices under test (DUTs), and to receive and perform measurement of response signals of the DUT, different ones of the test control circuit corresponding to different ones of the DUTs;
a transition control circuit configured to:
operate the test control circuit in response to a first operational state, the first operational state indicating a first mode and a first set of configuration settings;
receive a transition trigger signal and a second operational state, the second operational state indicating a second mode and a second set of configuration settings; and
transition the test control circuit, in response to receiving the transition trigger signal, to operating the test control circuit in response to the second operational state by performing allowed mode changes; and
an interface communication circuit coupled to control the test control circuits, the interface communication circuit configured to provide corresponding transition trigger signals and second operational states to respective ones of the test control circuits;
wherein allowed mode changes are restricted to: from a DUT driving mode to a DUT non-driving mode, from a DUT non-driving mode to another DUT non-driving mode, or from a DUT non-driving mode to a DUT driving mode.

15. The ATE of claim 14, wherein ones of the test control circuits are configured to not drive a signal to the DUT while respective test control circuits are in the DUT non-driving mode.

16. The ATE of claim 14, wherein the transition control circuit includes:
a control output;
a state register block including a first output and a second output, the state register block configured to store the first state and the second state;
a selection circuit including a first data input, a second data input, a control input, and an output, the first data input of the selection circuit coupled to the first output of the state register block, the second data input of the selection circuit coupled to the second output of the state register block, and the control input of the selection circuit is coupled to the control output of the control circuit, so that the selection circuit outputs the first data input of the selection circuit or the second data input of the selection circuit in response to the control output of the control circuit.

17. The ATE of claim 14, wherein ones of the test control circuits include a driving prevention circuit, the driving prevention circuit configured to:
drive a zero current signal to the DUT; or
use negative feedback to reduce a leakage signal from an open switch of the test control circuit adapted to couple an output of the test control circuit to an input of the DUT.

18. The ATE of claim 14, wherein ones of the control circuit include a lookup table configured to store multiple operating state transition super-set sequences, different ones of the operating state transition super-set sequences corresponding to each possible mode change path, wherein the possible mode change paths include a minimum number of mode changes and accord with the allowed mode changes.

19. The ATE of claim 18, wherein the transition control circuit includes an execution circuit configured to translate an operating state transition super-set sequence into a sequence of control signals for controlling the subsystem.

20. A test control circuit comprising:
a subsystem configured to output test signals to a device under test (DUT), and to receive and perform measurement of response signals of the DUT;
a memory storing multiple sets of sequenced operational state transition commands, and configured to store a first operational state information and a second operational state information; and
a transition control circuit configured to:
operate the test control circuit in response to the first operational state information, the first operational state information indicating a first mode and a first set of configuration settings;
receive a transition trigger signal;
transition the test control circuit, in response to receiving the transition trigger signal, to operating in response to the second operational state information, the second operational state information indicating a second mode and a second set of configuration settings;
wherein different ones of the sets of sequenced operational state transition commands correspond to different combinations of the first mode and the second mode; and
wherein the transition action includes transitioning the test control circuit from operating in response to the first mode and the first configuration settings, to operating in response to the second mode and the second configuration settings, in an order responsive to the set of sequenced operational state transition commands corresponding to the first mode and the second mode.
